(19) United States
(12) Patent Application Publication
(10) Pub. No.: US 2024/0161534 A1
(43) Pub. Date: May 16, 2024

(54) FINGERPRINT SENSOR MODULE AND METHOD FOR MANUFACTURING A FINGERPRINT SENSOR MODULE

(71) Applicant: FINGERPRINT CARDS ANACATUM IP AB, GÖTEBORG (SE)

(72) Inventor: Zhimin Mo, MÖLNDAL (SE)

(21) Appl. No.: 18/549,660

(22) PCT Filed: Mar. 10, 2022
(86) PCT No.: PCT/SE2022/050239

§ 371 Date: Sep. 8, 2023

(30) Foreign Application Priority Data
Mar. 23, 2021 (SE) 2150335-4

(51) Int. Cl. G06V 40/13; G06K 19/073

(52) U.S. Cl. CPC G06V 40/1306; G06K 19/07354; G06V 40/1329

(57) ABSTRACT

A fingerprint sensor module comprising: a carrier comprising a first recessed portion on a first side of the carrier; a fingerprint sensing device arranged in the first recessed portion of the carrier, the fingerprint sensing device comprising a fingerprint sensing surface; a second recessed portion on a second side of the carrier, opposite the first side, and at an edge of the carrier and a connection pad arranged in the second recessed portion; and an electrical connection through the carrier connecting the fingerprint sensing device to the connection pad.

### FIELD OF THE INVENTION

The present invention relates to a fingerprint sensing module suitable for integration in a smartcard and to a method for manufacturing such a fingerprint sensor module. In particular, the present invention describes a fingerprint sensor module enabling a reduction in thickness in comparison with a conventional fingerprint sensor module.

### BACKGROUND OF THE INVENTION

Various types of biometric systems are used more and more in order to provide increased security and/or enhanced user convenience. In particular, fingerprint sensing systems have been adopted in consumer electronic devices thanks to their small form factor, high performance, and user acceptance.

Among the various available fingerprint sensing principles (such as capacitive, optical, thermal etc.), capacitive sensing is most commonly used, in particular in applications where size and power consumption are important issues. All capacitive fingerprint sensors provide a measure indicative of the capacitance between each of several sensing structures and a finger placed on or moved across the surface of the fingerprint sensor.

To accurately measure the capacitance between the finger and a sensing structure, it is desirable that the finger can be held at a known reference potential. In commonly available fingerprint sensors used in smartphones and the like, the reference potential can be provided by means of an electrically conductive bezel arranged around the fingerprint sensor, where a finger placed on the sensor also contacts the bezel.

However, for fingerprint sensor integration in smartcards, which is increasingly requested by the market, the requirements of the fingerprint sensor may be different compared to for a sensor is used in a smartphone.

One aspect which is particularly important for a fingerprint sensor module for smartcard integration is the thickness of the module, where it is desirable to minimize the thickness to facilitate smartcard integration. Various solutions such as T-shaped sensor modules have helped to achieve thin fingerprint sensor module. However, there is still room for further improvement.

Accordingly, there is a need for an improved fingerprint sensor module having a low thickness making it suitable for integration in a smartcard.

### SUMMARY

In view of above-mentioned and other drawbacks of the prior art, it is an object of the present invention to provide a fingerprint sensor module suitable for integration in a smartcard. In particular, the present invention relates to a fingerprint sensor module having a reduced thickness in comparison to conventional sensor modules.

According to a first aspect of the invention, it is provided a fingerprint sensor module comprising: a carrier comprising a first recessed portion on a first side of the carrier; a fingerprint sensing device arranged in the first recessed portion of the carrier, the fingerprint sensing device comprising a fingerprint sensing surface; a second recessed portion on a second side of the carrier, opposite the first side, and at an edge of the carrier and a connection pad arranged in the second recessed portion; and an electrical connection through the carrier connecting the fingerprint sensing device to the connection pad.

The carrier may consist of one or more elements or layers as will be exemplified in the following, and the carrier may also be formed by different materials or from a combination of materials. The fingerprint sensing device is arranged in the first recessed portion so that the sensing surface is facing away from the carrier. Fingerprint image capture can be performed when a user places a finger on the sensing surface. Furthermore, the outermost surface of the fingerprint sensor module forming the actual sensing surface may comprise a cover layer, encapsulation layer or the like so that the user does not touch the fingerprint sensor device directly.

The first recessed portion of the carrier is defined by an area portion of the carrier having a surface plane which is lower than a surface plane of at least some of the surrounding surfaces. Accordingly, the first recessed portion may be enclosed by sidewalls on all sides, or it may be open on one or more sides.

The second recessed portion is located on the second side of the carrier which can be seen as the backside of the carrier. Analogously to the first recessed portion, the second recessed portion is defined as an area portion having a surface plane which is lower than the surface plane of at least one adjacent surface as seen from the second side of the carrier. In particular, the second recessed portion has a surface which is recessed in relation to a general backside surface plane of the carrier.

The electrical connection through the carrier enables the fingerprint sensing device to be connected to external circuitry outside of the fingerprint sensor module via the connection pad. Moreover, the electrical connection through the carrier may be formed in a horizontal direction, a vertical direction or a combination thereof as will be exemplified in the following description.

The fingerprint sensing device is a capacitive sensing device, where a fingerprint image is captured by determining the capacitive coupling between sensing structures of the sensing device and a finger placed on a sensing surface of the sensing device, and where the fingerprint image is acquired by specific readout circuitry. The readout circuitry may be fully or partially integrated in the same chip as the sensing circuit, or the readout circuitry may comprise circuitry arranged separately from the fingerprint sensing device.

The present invention is based on the realization that the thickness of a fingerprint sensor module can be reduced by arranging the fingerprint sensing device in a recess of a carrier instead of arranging the device directly on the carrier surface as is done in many conventional fingerprint sensor modules. Moreover, the second recessed portion on the backside of the carrier facilitates the formation of a T-shaped fingerprint sensor module where the connection pad in the second recessed portion can be used to connect the fingerprint sensor module to external circuitry in e.g. a smartcard without adding thickness to the module.

According to one embodiment of the invention, the fingerprint sensor module further comprises a bond pad on the first side of the carrier and a wire bond connecting the fingerprint sensing device to the bond pad, thereby providing a straightforward method of connecting the fingerprint sensor device to the carrier. The bond pad is subsequently connected to the electrical connection through the carrier such that a connection from the fingerprint sensor device to the connection pad in the second recessed portion is formed. The bond pad may be located adjacent to the fingerprint sensing device in the first recessed portion or it may be located on the adjacent elevated portion of the carrier.

According to one embodiment of the invention, the fingerprint sensor module further comprises a solder connection connecting the fingerprint sensing device to the carrier. This provides an alternative to wire bonding for connecting the fingerprint sensing device to the carrier. The fingerprint sensing device would then comprise backside contacts and the carrier comprise corresponding solder pads for forming the connection between the fingerprint sensing device and the carrier

According to one embodiment of the invention, the electrical connection through the carrier connecting the fingerprint sensing device to the connection pad comprises at least one conductive layer located in the plane of the carrier. Moreover, the electrical connection through the carrier connecting the fingerprint sensing device to the connection pad may comprise a first conductive layer and a second conductive layer located in the plane of the carrier, and a vertical via connection connecting the first conductive layer to the second conductive layer.

According to one embodiment of the invention, the carrier is a conductive substrate such as a metal leadframe. This has the advantage that the electrical connection through the substrate is formed by the substrate as such. However, if it is desirable to form a plurality of separate electrical connections, care must be taken to form separate conduction paths in the conductive substrate if possible.

According to one embodiment of the invention, the carrier comprises a single substrate and the first recessed portion is formed as a cavity in the substrate.

According to one embodiment of the invention, the carrier comprises a first substrate and a second substrate arranged on top of the first substrate, wherein the fingerprint sensing device is arranged on the first substrate. The second substrate may have an opening in which the fingerprint sensing device is arranged, or it may consist of two or more separate substrate elements such that the first recessed portion is formed by the boundaries of the second substrate. More particularly, the first portion can be seen as the exposed surface area of the first substrate which is lower than the plane of the surface of the second substrate.

According to embodiments of the invention the first substrate may be connected to the second substrate by means of wire bonding or through a solder connection.

According to one embodiment of the invention, the fingerprint sensor module further comprises: a cover layer covering the fingerprint sensing device and extending outside of first substrate; a conductive trace located on the cover layer; and a wire bond between the connection pad located in the second recessed portion of the carrier and the conductive trace of the cover layer. The cover layer which may be a layer of a smartcard will thereby cover and protect the fingerprint sensing device. The cover layer may thereby form the outer surface of the fingerprint sensor module to be touched by a user.

According to one embodiment of the invention a smartcard comprising the fingerprint sensor module further comprises: an outer layer comprising an opening in which the fingerprint sensor module is located; a conductive trace located on the outer layer; and a wire bond between the connection pad located in the second recessed portion of the carrier and the conductive trace of the outer layer.

According to a second aspect of the invention, it is provided a method for manufacturing a fingerprint sensor module. The method comprises: providing a carrier; forming a first recessed portion at a first side of the carrier; forming a second recessed portion on a second side of the carrier and at an edge of the carrier; forming a connection pad in the second recessed portion; arranging a fingerprint sensing device in the first recessed portion; and forming an electrical connection between the fingerprint sensing device and the connection pad.

Effects and features of this second aspect of the present invention are largely analogous to those described above in connection with the first aspect of the invention.

Further features of, and advantages with, the present invention will become apparent when studying the appended claims and the following description. The skilled person realize that different features of the present invention may be combined to create embodiments other than those described in the following, without departing from the scope of the present invention.

### BRIEF DESCRIPTION OF THE DRAWINGS

These and other aspects of the present invention will now be described in more detail, with reference to the appended drawings showing an example embodiment of the invention, wherein:

FIG. 1 schematically illustrates a fingerprint sensor module according to an embodiment of the invention;

FIG. 2 schematically illustrates a fingerprint sensor module according to an embodiment of the invention;

FIG. 3 schematically illustrates a fingerprint sensor module according to an embodiment of the invention;

FIGS. 4A-B schematically illustrate fingerprint sensor modules according to embodiments of the invention;

FIG. 5 schematically illustrates a fingerprint sensor module according to an embodiment of the invention;

FIG. 6 schematically illustrates a fingerprint sensor module according to an embodiment of the invention;

FIGS. 7A-D schematically illustrate steps of a method for manufacturing a fingerprint sensor module according to an embodiment of the invention;

FIG. 8 is a flow chart outlining steps of a method according to an embodiment of the invention;

FIGS. 9A-B schematically illustrate steps of a method for manufacturing a fingerprint sensor module according to an embodiment of the invention;

FIG. 10 is a flow chart outlining steps of a method according to an embodiment of the invention;

FIGS. 11A-B schematically illustrate steps of a method for manufacturing a fingerprint sensor module according to an embodiment of the invention; and

FIG. 12 is a flow chart outlining steps of a method according to an embodiment of the invention.

### DETAILED DESCRIPTION OF EXAMPLE EMBODIMENTS

In the present detailed description, various embodiments of the fingerprint sensor module according to the present invention are mainly described with reference to a fingerprint sensor module suitable for integration in a smartcard, and to a smartcard comprising such a sensor module. However, the sensor module may equally well be integrated in other devices such as electronic consumer devices, key fobs, and the like.

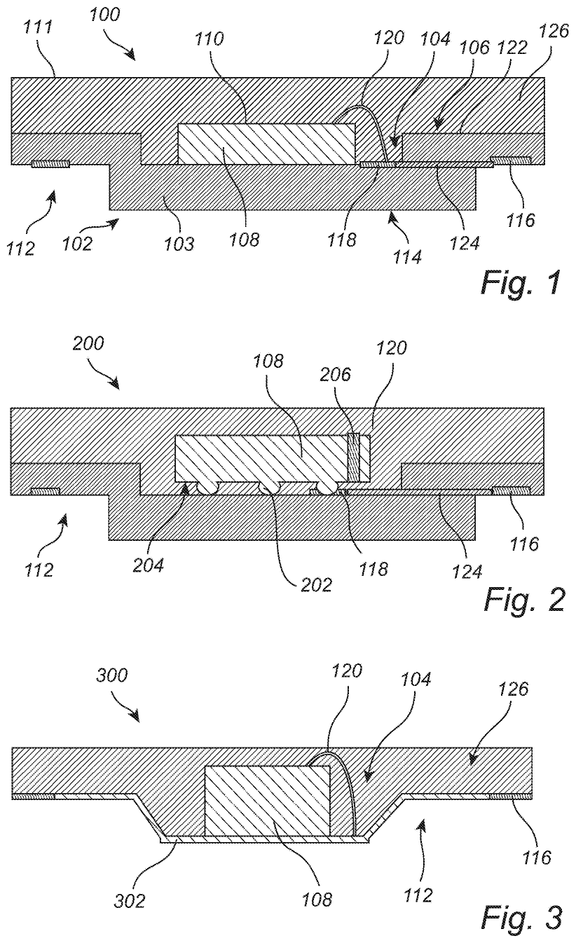

FIG. 1 is a schematic illustration of a fingerprint sensor module 100 comprising a carrier 102 in the form of a single substrate 103 comprising a first recessed portion 104 on a first side 106 of the substrate 103. A fingerprint sensing device 108 is arranged in the first recessed portion 104 of the substrate 103 and the fingerprint sensing device 108 comprises a fingerprint sensing surface 110. The sensing surface 110 is facing away from the carrier 102, and in the present context the top side 111 of the fingerprint sensor module 100 is the side on which a finger is placed for fingerprint imaging.

The fingerprint sensing device 108 is connected to a bond pad 118 located on the first side 106 of the substrate 103 adjacent to the fingerprint sensing device 108 by a wire bond 120. In FIG. 1, the bond pad 118 is located in the first recessed portion 104. However, the bond pad may equally well be located on the elevated portion 122 of the carrier 102. When using wire bonding to connect the fingerprint sensing device 108 to the bond pad 118, a lower height of the wire bond may be achieved by arranging the bond pad in the first recessed portion 104 as illustrated compared to for a bond located on the elevated portion 122.

The substrate 103 further comprises a second recessed portion 112 on a second side 114 of the carrier 102, opposite the first side, i.e. at the bottom of the fingerprint sensor module 100. Accordingly, the second recess 112 is defined as a recess in comparison to the surface plane of the second side 114 of the carrier 102. The second recessed portion 112 is located at an edge of the carrier 102, and in the present description two recessed portions 112 are formed at two opposing edges of the substrate 103 so that a fingerprint sensor module 100 having a T-shaped cross section profile is formed. It should be noted that recessed portions may be located at any number of edges of the carrier 102, such as at one, two, three or four edges of a rectangular carrier 102. Moreover, the two recessed portions 112 may extend along the full length of the edge of the carrier, or they may be formed at only a portion of the edge of the carrier.

A connection pad 116 is arranged in the second recessed portion 112 and an electrical connection is formed through the substrate 103, connecting the fingerprint sensing device 108 to the connection pad 116. The electrical connection is here formed by a conductive layer 124 arranged horizontally in the plane of the substrate 103. Moreover, the fingerprint sensing device 108 and the wire bond 120 are embedded in an encapsulation layer 126 protecting the components. Thereby, the second recessed portion 112 is offset in relation to the first recessed portion 104 in a direction of a plane of the substrate 103, i.e. in a horizontal direction which is the case for all embodiments as will be described in the following. Consequently, the connection pad 116 is offset in relation to the fingerprint sensing device 108 and the electrical connection is thereby formed to extend in the horizontal direction to enable a connection between the connection pad 116 and the fingerprint sensing device 108.

Furthermore, the second recessed portion 112 may be larger than the size of the connection pad 116 so that a plurality of connection pads 116 can be arranged in the same recessed portion 112 if required.

It is illustrated that the fingerprint sensing device 108 reaches above the upper surface 122 of the substrate 103. However, this is not required, and it is also feasible to configure the fingerprint sensor module 100 such that the surface 110 of the fingerprint sensing device 108 is in line with or below the upper surface of the carrier 102, i.e. in line with or below the elevated portion 122.

FIG. 2 schematically illustrates a fingerprint sensor module 200 which in many respects is similar to the fingerprint sensor module 100 of FIG. 1. The main difference is that the fingerprint sensing device 108 is connected to the carrier 102 by means of a solder connection 202 at the backside 204 of the fingerprint sensing device 108. The fingerprint sensing device 108 further comprises a via connection 206, such as a through-silicon via (TSV) connection, through the fingerprint sensing device 108.

FIG. 3 schematically illustrates a fingerprint sensor module 300 where the carrier is a conductive substrate such as a metal leadframe 302. The leadframe 302 can be bent/formed/shaped by a pressing tool to simultaneously form the first recessed portion 104 and the second recessed portion 112. Moreover, the wire bond 120 can in principle be connected directly to the substrate 302 and an electrical connection is thereby formed to the connection pad 116 by the substrate 302 as such. When using a conductive substrate 302 as illustrated, it must be ensured that the encapsulation material 126 does not leak through any openings in the substrate 302 and for this reason a flexible sealing film (not shown) is laminated to the backside of the substrate 302 during deposition of the encapsulant. After the encapsulation process, also referred to as molding, is completed, the sealing film can be removed.

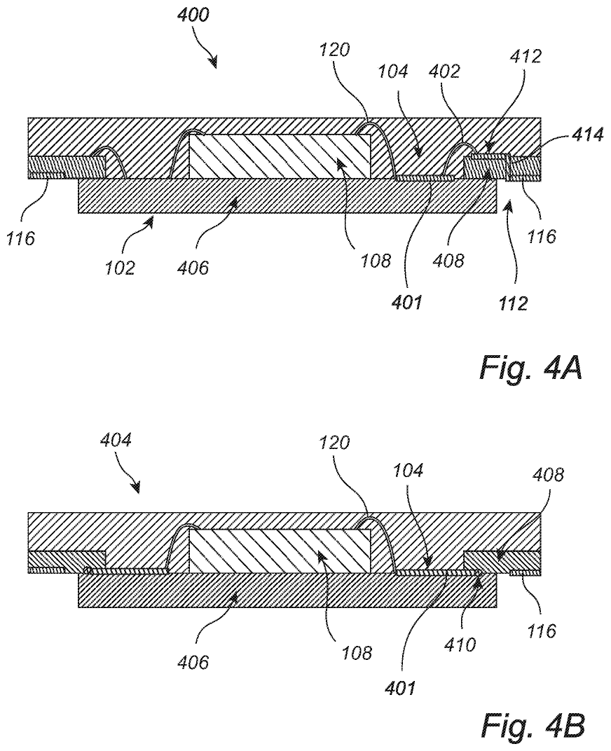

FIGS. 4A-B schematically illustrate fingerprint sensor modules 400, 404 where the carrier 102 comprises two separate substrates 406, 408. The carrier 102 comprises a first substrate 406 and a second substrate 408 arranged on top of the first substrate 406, wherein the fingerprint sensing device 108 is arranged on the first substrate 406. The second substrate 408 may consist of one or more elements arranged on the first substrate 406 to form the first and second recessed portions 104, 112.

In FIG. 4A, the electrical connection between the fingerprint sensing device 108 and the connection pad 116 is formed by a first wire bond 120 from the surface of the fingerprint sensing device 108 to a bond pad 401 on the first substrate and a second wire bond 402 between the first substrate 406 and the second substrate 408. The second substrate 408 further comprises a bond pad and/or conductive trace 412 and a via connection 414 through the substrate 408 electrically connecting the second wire bond 402 to the connection pad 116. FIG. 4B illustrates an embodiment where a solder connection 410 located between the first substrate 406 and the second substrate 408 forms an electrical connection between the first and second substrates 406, 408. The electrical connection (not shown) between the solder joint 410 and the connection pad 116 may consist of a conductive layer on the backside of or within the second substrate 408, and/or it may comprise via connections through the second substrate 408.

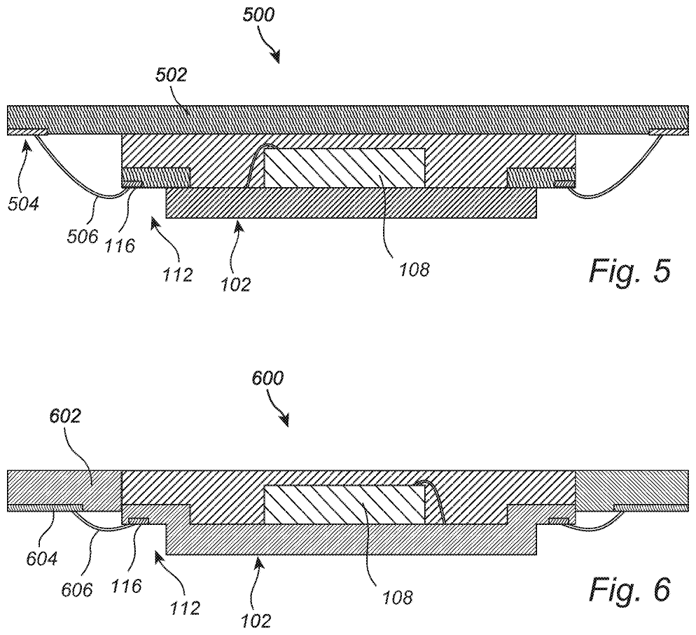

FIG. 5 schematically illustrates a fingerprint sensor module 500 further comprising a cover layer 502 covering the fingerprint sensing device 108 and extending outside of the carrier 102, a conductive trace 504 located on the cover layer 502 and a wire bond 506 between the connection pad 116 located in the second recessed portion 112 of the carrier 102 and the conductive trace 504 of the cover layer 502. Accordingly, the conductive trace 504 is facing in the same direction as the connection pad 116. The cover layer 502 may for example be a layer in a smartcard, such as an outer layer. Thereby, via the conductive trace 504 of the cover layer 502, the fingerprint sensing device 108 can be connected to smartcard circuitry such as an antenna, a secure element, or other components. Preferably, the wire bond 506 has a lowest point which is not lower than the bottom surface of the carrier 102. The total thickness of the fingerprint sensor module 500 is thereby defined by the cover layer and the module 500 as such and not by the wire bond 506 to the cover layer 502.

FIG. 6 schematically illustrates a fingerprint sensor module 600 arranged in an opening of an outer layer 602 of a smartcard 600. A wire bond 606 is arranged between the connection pad 116 located in the second recessed portion 112 of the carrier 102 and a conductive trace 604 of the outer layer 602. Similarly to the description above in relation to FIG. 5, the conductive trace enables the connection between the fingerprint sensing device 108 and other components of the smartcard. The embodiment where the fingerprint sensor module is located in an opening of a cover layer is advantageously used when it is desirable to minimize the distance between a finger and the fingerprint sensing device 108.

Even though FIGS. 5 and 6 illustrate the fingerprint sensor module 400 of FIG. 4, any of the above described and illustrated fingerprint sensor modules may be arranged under a cover layer or in the opening of the cover layer e.g. for integration in a smartcard in a similar manner as described.

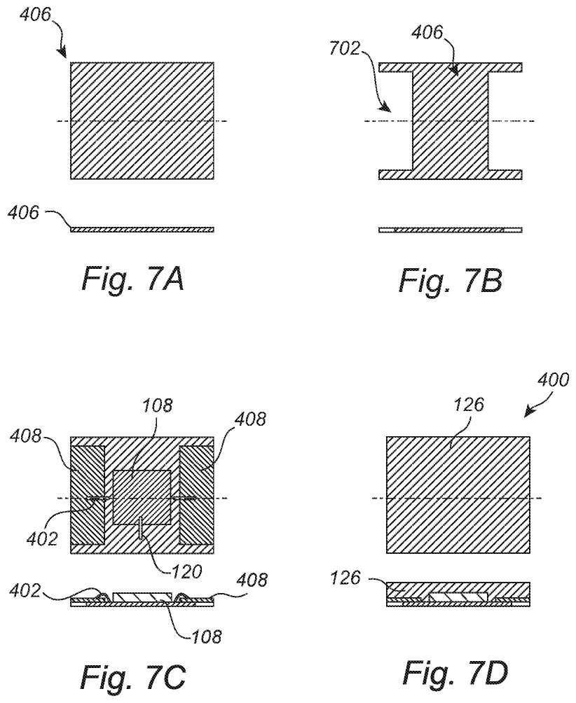

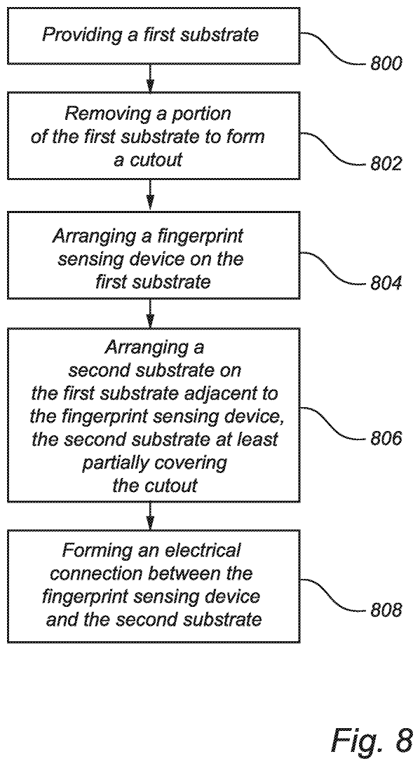

FIGS. 7A-D schematically illustrate steps of forming a fingerprint sensor module and FIG. 8 is a flow chart outlining the general steps of the method. In FIGS. 7A-D both a top view and a cross section view is shown to clearly outline the module during different steps of the manufacturing method. The following description will focus on the formation of the carrier comprising a first and second recess since it can be assumed that the skilled person is familiar with steps such as wire bonding and soldering to form electrical connections.

The method comprises providing 800 a first substrate 406 as illustrated in FIG. 7A which is followed by removing 802 a portion of a side of the first substrate to form a cutout 702 illustrated in FIG. 7B.

Next, a fingerprint sensing device 108 is arranged 804 on the first substrate 406 and a second substrate 408 is arranged 806 on the first substrate 406 adjacent to the fingerprint sensing device 108 such that the second substrate 408 at least partially covers the cutout 702 as illustrated FIG. 7C. The first and second substrates 406, 408 may be of the same type, such as a suitable PCB substrate. In the illustrated example, cutouts 702 are formed on opposing sides of a rectangular first substrate 406, and the second substrate 408 consist of two separate elements, each one fully covering a corresponding cutout 702. It should be noted that the steps of arranging the second substrate 408 and fingerprint sensing device 102 on the first substrate may be performed in any suitable order. The first recessed portion 104 is then formed on the first substrate 406 in relation to the second substrate 408. Correspondingly, the second recessed portion is formed on the backside of the carrier by the difference in height between the first and second substrates 406, 408.

The next step, also illustrated in FIG. 7C, comprises forming 808 an electrical connection between the fingerprint sensing device 108 and second substrate 408, here illustrated by a plurality of wire bonds 120 connecting the fingerprint sensing device 108 to the first substrate 406 and a plurality of wire bonds 402 connecting the first substrate 406 to the second substrate 408. The wire bonds are preferably connected to bond pads (not shown) arranged on the first and/or second substrates 406, 408. In practice, wire bonds can be formed between any two points of the fingerprint sensor module.

In the final step illustrated in FIG. 7D, an encapsulation layer 126 is deposited to protect the fingerprint sensing device 102 and to form the final fingerprint sensor module 400.

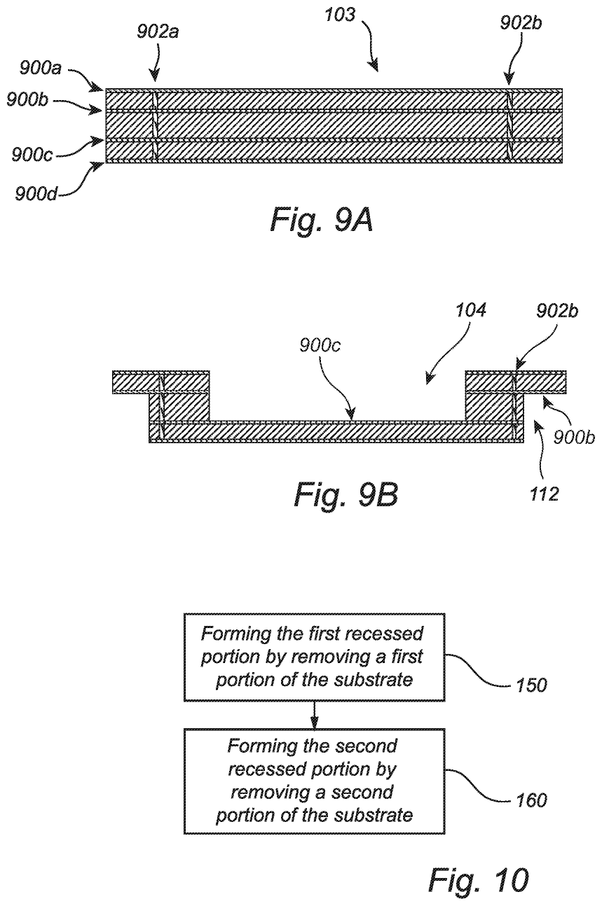

FIGS. 9A-B schematically illustrate steps of forming a fingerprint sensor module and FIG. 10 is a flow chart outlining the general steps of the method. In FIGS. 9A-B, the carrier is formed from a single substrate 103 as illustrated in FIG. 9A. The substrate can for example be a layered structure such as a PCB substrate of type FR-4. The substrate 103 comprises a plurality of conductive layers 900a-d extending horizontally in the plane of the substrate 103 and vertical via connections 902a-b connecting the conductive layers 900a-d to each other.

The method comprises forming 150 the first recessed portion 104 by removing a first portion of the substrate 103 and forming 160 the second recessed portion 112 by removing a second portion of the substrate. The first and second recessed portions 104, 112 can for example be formed by machining the substrate 103. The following steps of arranging a fingerprint sensing device in the first recessed portion 104 are similar to those described above in relation to FIGS. 7C-D.

The electrical connection between a fingerprint sensing device 108 in the first recessed portion 104 and a connection pad in the second recessed portion 112 is formed by connecting the fingerprint sensing device 108 to the exposed conductive layer 900c in the first recessed portion 104, through a vertical via connection 902b and on to another conductive layer 900b exposed in the second recessed portion 112.

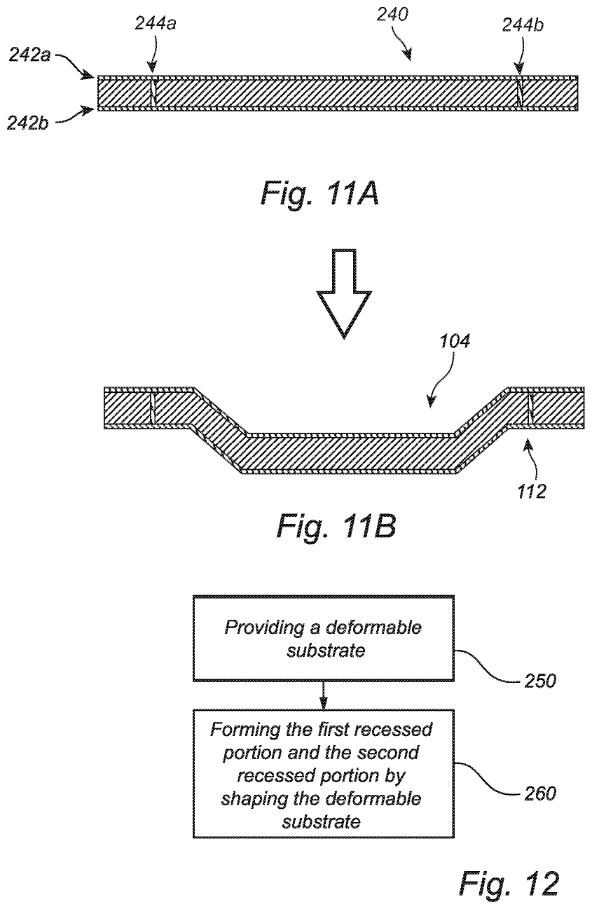

FIGS. 11A-B schematically illustrate steps of forming a fingerprint sensor module and FIG. 12 is a flow chart outlining the general steps of the method. In FIGS. 11A-B, the carrier is formed from a single deformable substrate 240 as illustrated in FIG. 11A. The method first comprises providing 250 a deformable substrate 240 comprising two or more conductive layers 242a-b extending horizontally in the plane of the substrate 240, and vertical via connections 244a-b connecting the conductive layers 242a-b to each other. Next, the substrate 240 is shaped 260 to form the first recessed portion 104 and the second recessed portion 112, for example by using a pressing tool, a stamping tool or the like. The electrical connection between a fingerprint sensing device in the first recessed portion 104 and a connection pad in the second recessed portion 112 is formed in a similar manner as described above with reference to FIG. 9B.

Even though the invention has been described with reference to specific exemplifying embodiments thereof, many different alterations, modifications and the like will become apparent for those skilled in the art. Also, it should be noted that parts of the fingerprint sensor module may be omitted, interchanged or arranged in various ways, the fingerprint sensor module yet being able to perform the functionality of the present invention.

Additionally, variations to the disclosed embodiments can be understood and effected by the skilled person in practicing the claimed invention, from a study of the drawings, the disclosure, and the appended claims. In the claims, the word “comprising” does not exclude other elements or steps, and the indefinite article “a” or “an” does not exclude a plurality. The mere fact that certain measures are recited in mutually different dependent claims does not indicate that a combination of these measures cannot be used to advantage.

1. A fingerprint sensor module comprising:
a carrier comprising a first recessed portion on a first side of the carrier;
a fingerprint sensing device arranged in the first recessed portion of the carrier, the fingerprint sensing device comprising a fingerprint sensing surface;
a second recessed portion on a second side of the carrier, opposite the first side, and at an edge of the carrier and a connection pad arranged in the second recessed portion; and
an electrical connection through the carrier connecting the fingerprint sensing device to the connection pad.

2. The fingerprint sensor module according to claim 1, further comprising a bond pad on the first side of the carrier and a wire bond connecting the fingerprint sensing device to the bond pad.

3. The fingerprint sensor module according to claim 1, further comprising a solder connection connecting the fingerprint sensing device to the carrier.

4. The fingerprint sensor module according to claim 1, wherein the electrical connection through the carrier connecting the fingerprint sensing device to the connection pad comprises at least one conductive layer located in the plane of the carrier.

5. The fingerprint sensor module according to claim 1, wherein the electrical connection through the carrier connecting the fingerprint sensing device to the connection pad comprises a first conductive layer and a second conductive layer located in the plane of the carrier, and a vertical via connection connecting the first conductive layer to the second conductive layer.

6. The fingerprint sensor module according to claim 1, wherein the carrier is a conductive substrate.

7. The fingerprint sensor module according to claim 6, wherein the conductive substrate is a metal leadframe.

8. The fingerprint sensor module according to claim 1, wherein the carrier comprises a single substrate and wherein the first recessed portion is formed as a cavity in the substrate.

9. The fingerprint sensor module according to claim 1, wherein the carrier comprises a first substrate and a second substrate arranged on top of the first substrate, wherein the fingerprint sensing device is arranged on the first substrate.

10. The fingerprint sensor module according to claim 9, further comprising a wire bond between the first substrate and the second substrate.

11. The fingerprint sensor module according to claim 9, further comprising a solder connection between the first substrate and the second substrate.

12. The fingerprint sensor module according to claim 1, further comprising:
a cover layer covering the fingerprint sensing device and extending outside of the carrier;
a conductive trace located on the cover layer; and
a wire bond between the connection pad located in the second recessed portion of the carrier and the conductive trace of the cover layer.

13. The fingerprint sensor module according to claim 12, wherein the cover layer is a layer of a smartcard.

14. A smartcard comprising a fingerprint sensor module according to claim 1.

15. The smartcard according to claim 14, comprising:
an outer layer comprising an opening in which the fingerprint sensor module is located;
a conductive trace located on the outer layer; and
a wire bond between the connection pad located in the second recessed portion of the carrier and the conductive trace of the outer layer.

16. Method for manufacturing a fingerprint sensor module, the method comprising:
forming a first recessed portion on a first side of a carrier;
forming a second recessed portion on a second side of the carrier and at an edge of the carrier;
forming a connection pad in the second recessed portion;
arranging a fingerprint sensing device in the first recessed portion; and
forming an electrical connection between the fingerprint sensing device and the connection pad.

17. The method according to claim 16, wherein the carrier comprises a first substrate and a second substrate, the method comprising:
providing a first substrate;
removing a portion of the first substrate to form a cutout;
arranging a fingerprint sensing device on the first substrate;
arranging a second substrate on the first substrate adjacent to the fingerprint sensing device, the second substrate at least partially covering the cutout; and
forming an electrical connection between the fingerprint sensing device and the second substrate.

18. The method according to claim 16, wherein the carrier comprises a single substrate, the method comprising:
forming the first recessed portion by removing a first portion of the substrate;
forming the second recessed portion by removing a second portion of the substrate.

19. The method according to claim 16, wherein the carrier comprises a single substrate, the method comprising:
providing a deformable substrate; and
forming the first recessed portion and the second recessed portion by shaping the deformable substrate.
